(19) United States
(12) Patent Application Publication
(10) Pub. No.: US 2026/0112579 A1
(43) Pub. Date: Apr. 23, 2026

(54) SUBSTRATE TREATMENT APPARATUS FOR POWER CALIBRATION

(71) Applicant: SAMSUNG ELECTRONICS CO., LTD., Suwon-si (KR)

(72) Inventor: Won Hee LEE, Suwon-si (KR)

(73) Assignee: SAMSUNG ELECTRONICS CO., LTD., Suwon-si (KR)

(21) Appl. No.: 19/363,125

(22) Filed: Oct. 20, 2025

(30) Foreign Application Priority Data
Oct. 21, 2024 (KR) 10-2024-0144371
Mar. 6, 2025 (KR) 10-2025-0028705

(51) Int. Cl. H01J 37/32; G05B 19/4099

(52) U.S. Cl. CPC H01J 37/32183; G05B 19/4099; H01J 37/32899; G05B 2219/45031; H01J 2237/24564

(57) ABSTRACT

Provided is a substrate treatment apparatus, and a method of operating same, the substrate treatment apparatus including: a first process chamber configured to provide a treatment to a substrate; a first radio frequency (RF) generator configured to generate a first RF signal; a first RF matcher configured to match an impedance between the first RF generator and the first process chamber and to provide the first RF signal to the first process chamber; a first RF meter configured to measure a power of the first RF signal; and a first switcher configured to connect the first RF generator to either the first RF matcher or the first RF meter.

### CROSS-REFERENCE TO RELATED APPLICATION

This application is based on and claims priority to Korean Patent Application No. 10-2024-0144371, filed in the Korean Intellectual Property Office on Oct. 21, 2024, and Korean Patent Application No. 10-2025-0028705, filed in the Korean Intellectual Property Office on Mar. 6, 2025, the contents of which are herein incorporated by reference in their entireties.

### BACKGROUND

### 1. Field

The present disclosure relates to a substrate treatment apparatus.

### 2. Description of Related Art

In order to manufacture a semiconductor device, various processes such as photolithography, etching, ashing, ion implantation, thin film deposition, and cleaning are performed on a substrate to form a desired pattern on the substrate. Among these processes, the etching process is a process of removing a selected heating area among films formed on the substrate, and includes wet etching and dry etching. An etching device using plasma is used for dry etching.

In general, for uniformity and stability of the process, it is required to appropriately control and constantly manage parameters of the etching process. For example, the main parameters of the etching process may include radio-frequency power (RF Power), gas flow, pressure, temperature, etc.

The other parameters may be self-checked and verified within equipment, but in the case of radio-frequency power, it is necessary to separately attach an external device for inspection. Therefore, a substrate treatment apparatus capable of self-checking and verifying within equipment is required even in case of radio-frequency power.

### SUMMARY

Provided is a substrate treatment apparatus having consistent conditions.

Further provided is a substrate treatment apparatus designed to improve uniformity and stability of a process.

According to an aspect of the disclosure, a substrate treatment apparatus includes: a first process chamber configured to provide a treatment to a substrate; a first radio frequency (RF) generator configured to generate a first RF signal; a first RF matcher configured to match an impedance between the first RF generator and the first process chamber and to provide the first RF signal to the first process chamber; a first RF meter configured to measure a power of the first RF signal; and a first switcher configured to connect the first RF generator to either the first RF matcher or the first RF meter.

According to an aspect of the disclosure, a method for operating a substrate treatment apparatus includes: connecting a first radio frequency (RF) generator of the substrate treatment apparatus to an RF meter by a first switcher of the substrate treatment apparatus; measuring, by the RF meter, a power of a first RF signal generated by the first RF generator; providing, to the first RF generator, calibration data generated based on a first measured power measured by the RF meter and a first set power set to be output by the first RF generator; providing, to the RF meter by the first RF generator, a second RF signal calibrated based on the calibration data; measuring, by the RF meter, a power of the second RF signal; and based on a second measured power measured by the RF meter being the same as the first set power, disconnecting the first RF generator from the RF meter by the first switcher.

According to an aspect of the disclosure, a substrate treatment apparatus includes: a first process chamber configured to provide a treatment to a substrate; a second process chamber different from the first process chamber; a first radio frequency (RF) generator configured to generate a first RF signal; a second RF generator configured to generate a second RF signal; a first RF matcher configured to match an impedance between the first RF generator and the first process chamber and to provide the first RF signal to the first process chamber; a second RF matcher configured to match an impedance between the second RF generator and the second process chamber and to provide the second RF signal to the second process chamber; an RF meter configured to measure a power of the first RF signal or a power of the second RF signal; a dummy loader configured to consume power received by the dummy loader from the RF meter; a first switcher configured to connect the first RF generator to either the first RF matcher or the RF meter; and a second switcher configured to connect the second RF generator to either the second RF matcher or the RF meter.

The objects of the present disclosure are not limited to those mentioned above, and additional objects of the present disclosure, which are not mentioned herein, will be clearly understood by those skilled in the art from the following description of the present disclosure.

Details of one or more embodiments are included in the detailed description and drawings.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram illustrating a substrate treatment apparatus according to one or more embodiments of the present disclosure;

FIG. 2 is a block diagram illustrating an operation of a substrate treatment apparatus according to one or more embodiments of the present disclosure;

FIG. 3 is a flow chart illustrating an operation of a substrate treatment apparatus according to one or more embodiments of the present disclosure;

FIGS. 4 to 7 are block diagrams illustrating an operation of the substrate treatment apparatus according to one or more embodiments of the present disclosure;

FIG. 8 is a block diagram illustrating a substrate treatment apparatus according to one or more embodiments of the present disclosure;

FIGS. 9 and 10 are perspective views illustrating a substrate treatment apparatus according to one or more embodiments of the present disclosure;

FIG. 11 is a plan view illustrating a substrate treatment apparatus according to one or more embodiments of the present disclosure;

FIG. 12 is a block diagram illustrating a substrate treatment apparatus according to one or more embodiments of the present disclosure;

FIG. 13 is a plan view illustrating a substrate treatment apparatus according to one or more embodiments of the present disclosure;

FIG. 14 is a block diagram illustrating a substrate treatment apparatus according to one or more embodiments of the present disclosure; and

FIGS. 15 and 16 are block diagrams illustrating a substrate treatment apparatus according to one or more embodiments of the present disclosure.

### DETAILED DESCRIPTION

Hereinafter, the embodiments of the present disclosure will be described in detail with reference to the accompanying drawings. The same reference numerals will be used for the same elements on the drawings and a repeated description of the corresponding elements will be omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

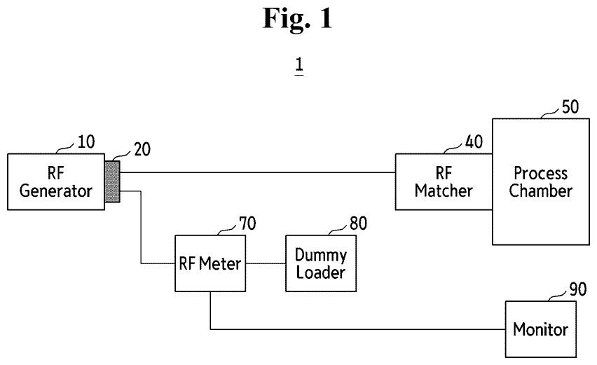

FIG. 1 is a block diagram illustrating a substrate treatment apparatus according to one or more embodiments of the present disclosure.

Referring to FIG. 1, a substrate treatment apparatus 1 may include an RF generator 10, a switcher 20, an RF matcher 40, a process chamber 50, an RF meter 70, and a dummy loader 80.

The RF generator 10 and the RF matcher 40, the RF generator 10 and the RF meter 70, the RF meter 70 and the process chamber 50, and the RF meter 70 and the dummy loader 80 may be respectively connected by a plurality of cables.

The RF generator 10 generates an RF power signal required to perform a process in the chamber, including the generation of plasma.

In one or more embodiments, the RF generator 10 may generate an RF signal corresponding to a set power for operating the process chamber 50 and provide the RF signal to the RF matcher 40 or the RF meter 70. For example, the RF generator 10 may generate a first RF signal that allows a first set power to be transmitted to the process chamber 50.

The switcher 20 may provide an output of the RF generator 10 to either the RF meter 70 or the RF matcher 40. For example, when the switcher 20 is in a first state, the RF signal output from the RF generator 10 may be provided to the RF matcher 40 through the switcher 20. In contrast, when the switcher 20 is in a second state, the RF signal output from the RF generator 10 may be provided to the RF meter 70 through the switcher 20. For example, the second state may be an idle state of the process chamber 50. The idle state may mean a state in which the process chamber 50 is not operated.

The RF matcher 40 may receive the RF signal from the RF generator 10 and perform impedance matching of the RF signal so that the RF power may be forwarded to the process chamber 50 in an optimized state. As a result, signal loss may be minimized and efficiency may be increased.

The process chamber 50 may load a substrate therein, and various semiconductor manufacturing processes may be performed in the process chamber 50. For example, the process chamber 50 may perform an etching process and/or a deposition process with respect to the substrate by using plasma. For example, the substrate treatment apparatus 1 may perform a Bosch process of repeatedly performing an etching process and a deposition process with respect to the substrate by using plasma.

Plasma may be generated in various ways. For example, the substrate treatment apparatus 1 may generate plasma by using methods such as a capacitor couple plasma (CCP), an inductively coupled plasma (ICP), or a magnetically enhanced reactive ion etching (MERIE), but the present disclosure is not limited thereto. The substrate treatment apparatus 1 may generate plasma in other ways to process the substrate.

The RF meter 70 may receive the RF signal from the RF generator 10. The RF meter 70 may measure the amplitude and frequency of the RF signal, and may measure the power of the RF signal. For example, the RF meter 70 may receive the first RF signal from the RF generator 10 and measure the power of the first RF signal by measuring the amplitude and frequency of the first RF signal. The measured power of the first RF signal, which is measured by the RF meter 70, may be a first measured power.

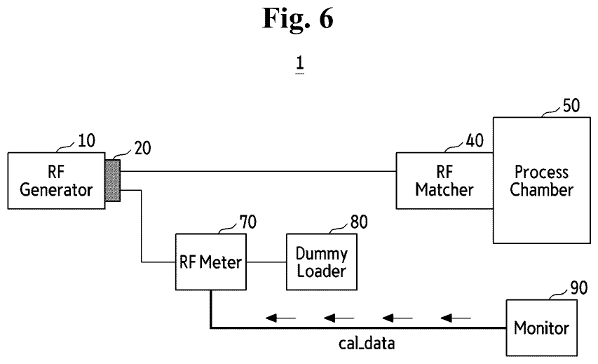

In addition, the RF meter 70 may provide calibration data (cal_data of FIG. 6) generated based on the set power value and the measured power value of the RF generator 10. For example, the calibration data cal_data may be determined based on a difference between the first set power value and the first measured power value, but the present disclosure is not limited thereto. As a result, it is possible to verify whether the set power value is properly output by the RF generator 10, and to calibrate any difference between the set power and the measured power.

In one or more embodiments, while the process chamber 50 is in an idle state, the RF meter 70 may measure the power of the RF signal generated by the RF generator 10 in accordance with a predetermined period and calibrate the difference between the measured power and the set power of the RF generator 10. A detailed description of the power verification and calibration method using the RF meter 70 will be described later.

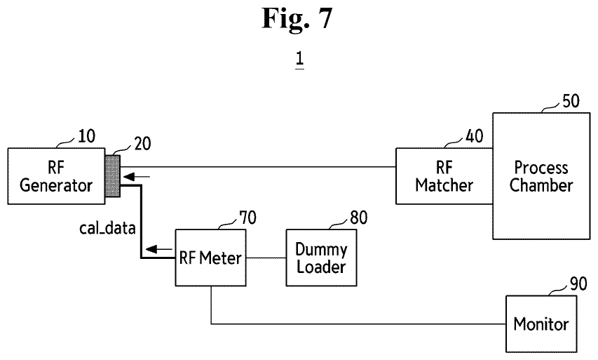

A monitor 90 may receive monitoring data (mon_data of FIG. 7) from the RF meter 70 and display the same. Also, the monitor 90 may include a user interface, and may receive the calibration data (cal_data of FIG. 7) from a user. For example, the user interface may be implemented as a device such as a button, a touch pad, a mouse and a keyboard, or may be implemented as a touch screen capable of performing the above-described function and a manipulation input function of the monitor 90. The monitor 90 may provide the calibration data cal_data received from the user to the RF meter 70.

In one or more embodiments, the monitor 90 may be arranged outside the process chamber 50, but the embodiments of the present disclosure are not limited thereto. In one or more other embodiments, the monitor 90 may be embedded in the process chamber 50.

The dummy loader 80 may receive the RF power from the RF meter 70. The dummy loader 80 may prevent electromagnetic interference by consuming the RF power. For example, the dummy loader 80 may be a resistor having a resistance of 50Ω.

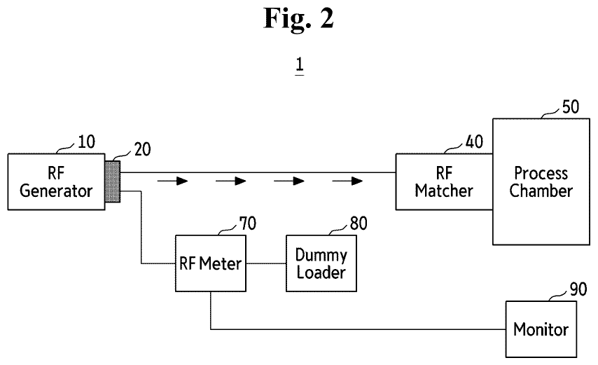

FIG. 2 is a block diagram illustrating an operation of a substrate treatment apparatus according to one or more embodiments of the present disclosure.

Referring to FIG. 2, when the process chamber 50 is in operation, the switcher 20 may connect the RF generator 10 to the RF matcher 40. Accordingly, the RF signal output from the RF generator 10 may be provided to the RF matcher 40 along a cable.

For example, the RF generator 10 may be set to output a first RF signal corresponding to a first operating power to operate the process chamber 50. The RF generator 10 may generate the first RF signal and provide the first RF signal to the RF matcher 40. The RF matcher 40 may match impedance of the RF generator 10 with impedance of the process chamber 50 and provide the first RF signal to the process chamber 50.

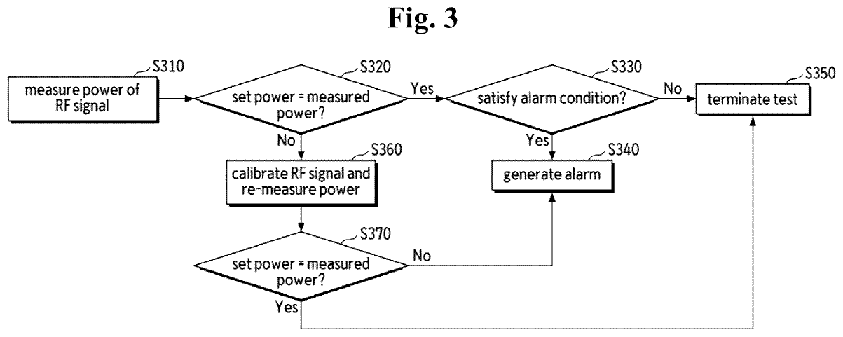

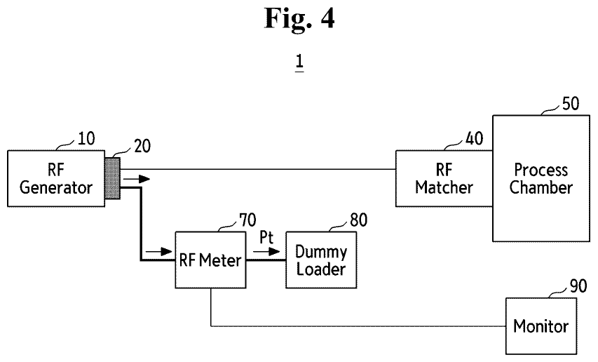

FIG. 3 is a flow chart illustrating an operation of a substrate treatment apparatus according to one or more embodiments of the present disclosure. FIGS. 4 to 7 are block diagrams illustrating an operation of the substrate treatment apparatus according to one or more embodiments of the present disclosure.

Referring to FIGS. 3 and 4, in an idle state in which the process chamber 50 is not operating, the switcher 20 may connect the RF generator 10 to the RF meter 70. Accordingly, the RF signal output from the RF generator 10 may be provided to the RF meter 70 along a cable.

The RF meter 70 may measure the power of the RF signal output from the RF generator 10 (S310). For example, the RF generator 10 may provide the first RF signal to the RF meter 70. The power of the first RF signal, which is measured by the RF meter 70, may be the first measured power.

The RF meter 70 may determine the identity by comparing the set power value set to be output by the RF generator 10 with the measured power value actually measured by the RF meter 70 (S320). For example, the RF meter 70 may compare the first set power set to be output from the RF generator 10 with the first measured power.

When the set power value and the measured power value are the same as each other (Yes), it may be determined whether an abnormality requiring an alarm for a user has occurred in the substrate treatment apparatus 1 (S530). For example, the RF meter 70 may determine whether an abnormality other than the power of the signal output from the RF generator 10 has occurred.

When the alarm is required (Yes), the RF meter 70 may generate the alarm (S340).

When the alarm is not required (No), a test by the RF meter 70 may be terminated (S350). After the test is completed, the power of the RF signal provided to the RF meter 70 may be provided to the dummy loader 80. The dummy loader 80 may prevent electromagnetic interference by consuming the RF power.

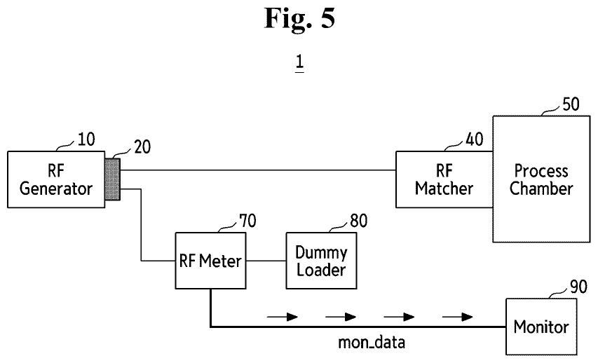

Referring to FIGS. 3 and 5, when the set power value set to be output by the RF generator 10 and the measured power value actually measured by the RF meter 70 are different from each other (No), the RF meter 70 may perform calibration for the set power (S360).

More specifically, the RF meter 70 may provide monitoring data mon_data to the monitor 90. For example, the monitoring data mon_data may be data including set power and/or measured power.

Referring to FIGS. 3 and 6, in one or more embodiments, the RF meter 70 may receive the calibration data cal_data, which is input from the user, from the monitor 90, but the present disclosure is not limited thereto, and the RF meter 70 may generate the calibration data cal_data by using the set power and the measured power.

Referring to FIGS. 3 and 7, the RF meter 70 may provide the calibration data cal_data to the RF generator 10. The RF generator 10 may output a calibrated RF signal by using the calibration data cal_data. For example, the RF generator 10 may provide a second RF signal, which is calibrated from the first RF signal, to the RF meter 70.

Referring to FIGS. 3 and 4, the RF meter 70 may re-measure the power of the RF signal output from the RF generator 10 (S360).

For example, the RF generator 10 may provide the second RF signal to the RF meter 70. The power of the second RF signal, which is measured by the RF meter 70, may be a second measured power.

The RF meter 70 may determine the identity by comparing the set power value set to be output by the RF generator 10 with the measured power value actually measured by the RF meter 70 (S370). For example, the RF meter 70 may compare the first set power set to be output from the RF generator 10 with the second measured power.

When the set power value and the measured power value are the same as each other (Yes), the test by the RF meter 70 may be terminated (S350). After the test is completed, the power of the RF signal provided to the RF meter 70 may be provided to the dummy loader 80. The dummy loader 80 may prevent electromagnetic interference by consuming the RF power.

When the set power value and the measured power value are different from each other (No), the RF meter 70 may generate an alarm (S340).

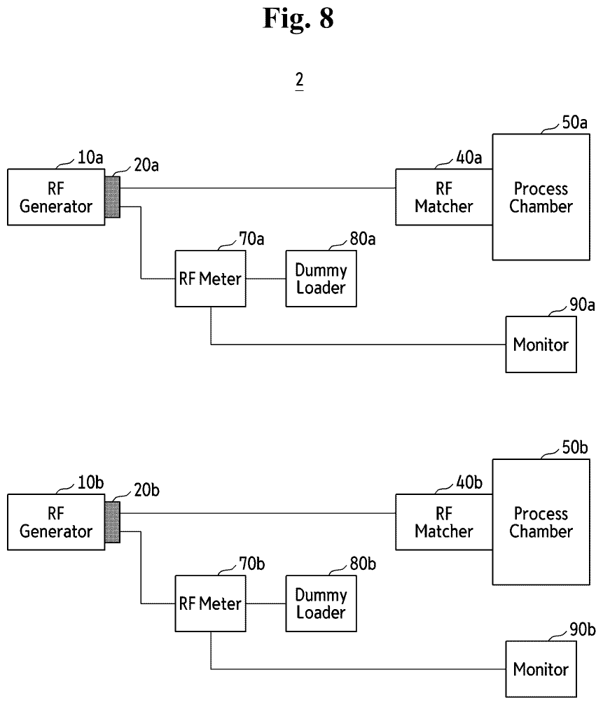

FIG. 8 is a block diagram illustrating a substrate treatment apparatus according to one or more embodiments of the present disclosure.

Referring to FIG. 8, a substrate treatment apparatus 2 may include a first RF generator 10a, a first switcher 20a, a first RF matcher 40a, a first process chamber 50a, a first RF meter 70a, a first dummy loader 80a, a first monitor 90a, a second RF generator 10b, a second switcher 20b, a second RF matcher 40b, a second process chamber 50b, a second RF meter 70b, a second dummy loader 80b, and a second monitor 90b. That is, the substrate treatment apparatus 2 may include a plurality of process chambers 50. Each process chamber 50 may operate by being independently connected to the RF generator 10, the switcher 20, the RF matcher 40, the RF meter 70, the dummy loader 80, and the monitor 90.

The first RF generator 10a and the second RF generator 10b may correspond to the RF generator 10 described with reference to FIG. 1. The first switcher 20a and the second switcher 20b may correspond to the switcher 20 described with reference to FIG. 1. The first RF matcher 40a and the second RF matcher 40b may correspond to the RF matcher 40 described with reference to FIG. 1. The first process chamber 50a and the second process chamber 50b may correspond to the process chamber 50 described with reference to FIG. 1. The first RF meter 70a and the second RF meter 70b may correspond to the RF meter 70 described with reference to FIG. 1. The first dummy loader 80a and the second dummy loader 80b may correspond to the dummy loader 80 described with reference to FIG. 1. The first monitor 90a and the second monitor 90b may correspond to the monitor 90 described with reference to FIG. 1. Therefore, for convenience of description, the description of each element of FIG. 8 will be omitted.

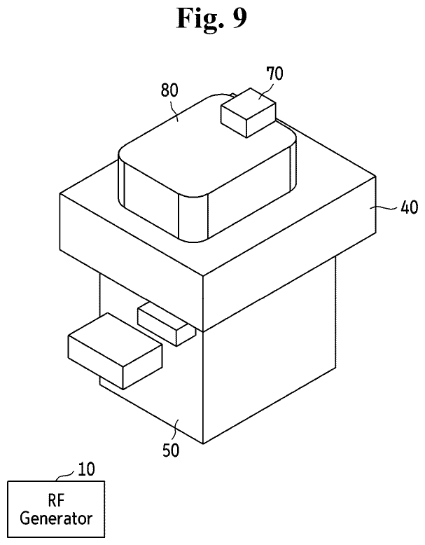

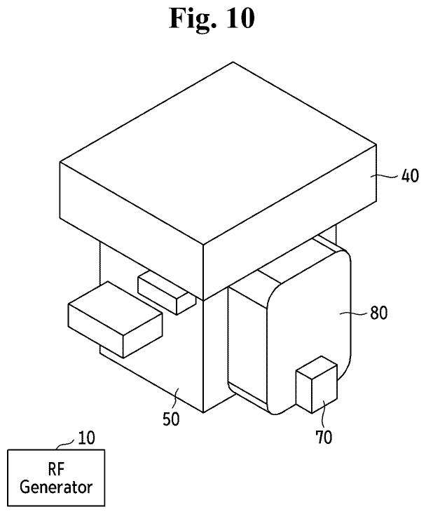

FIGS. 9 and 10 are perspective views illustrating a substrate treatment apparatus according to one or more embodiments of the present disclosure.

Referring to FIGS. 8 and 9, in one or more embodiments, the first RF meter 70a, the first dummy loader 80a, the second RF meter 70b, and the second dummy loader 80b may be embedded in the substrate treatment apparatus 2. For example, the first RF meter 70a and the first dummy loader 80a may be attached to an upper portion of the first process chamber 50a, and may be connected to the first RF generator 10a by the first switcher 20a. The second RF meter 70b and the second dummy loader 80b may be attached to an upper portion of the second process chamber 50b, and may be connected to the second RF generator 10b by the second switcher 20b. That is, in the substrate treatment apparatus 2 including a plurality of process chambers 50, each process chamber 50 may include an RF meter 70 and a dummy loader 80.

Since the RF meter 70 and the dummy loader 80 are embedded in the substrate treatment apparatus 2, the RF meter 70 may measure the RF power provided to the process chamber 50 and calibrate the RF power if necessary. The process of measuring and calibrating the power of the RF meter 70 with respect to the signal generated by the RF generator 10 may be repeated every predetermined period. That is, the substrate treatment apparatus 2 capable of self-checking may be provided. As a result, the substrate treatment apparatus 2 having improved accuracy may be provided.

Referring to FIGS. 8 and 10, in one or more embodiments, the first RF meter 70a, the first dummy loader 80a, the second RF meter 70b, and the second dummy loader 80b may be embedded in the substrate treatment apparatus 2. For example, the first RF meter 70a and the first dummy loader 80a may be attached to a sidewall of the first process chamber 50a and connected to the first RF generator 10a by the first switcher 20a. The second RF meter 70b and the second dummy loader 80b may be attached to a sidewall of the second process chamber 50b and connected to the second RF generator 10b by the second switcher 20b. That is, in the substrate treatment apparatus 2 including a plurality of process chambers 50, each process chamber 50 may include an RF meter 70 and a dummy loader 80.

As the RF meter 70 and the dummy loader 80 are embedded in the substrate treatment apparatus 2, the RF meter 70 may measure the RF power provided to the process chamber 50 every constant period and calibrate the RF power if necessary. The process of measuring and calibrating the power of the RF meter 70 with respect to the signal generated by the RF generator 10 may be repeated every constant period. That is, the substrate treatment apparatus 2 capable of self-checking may be provided. As a result, the substrate treatment apparatus 2 having improved accuracy may be provided.

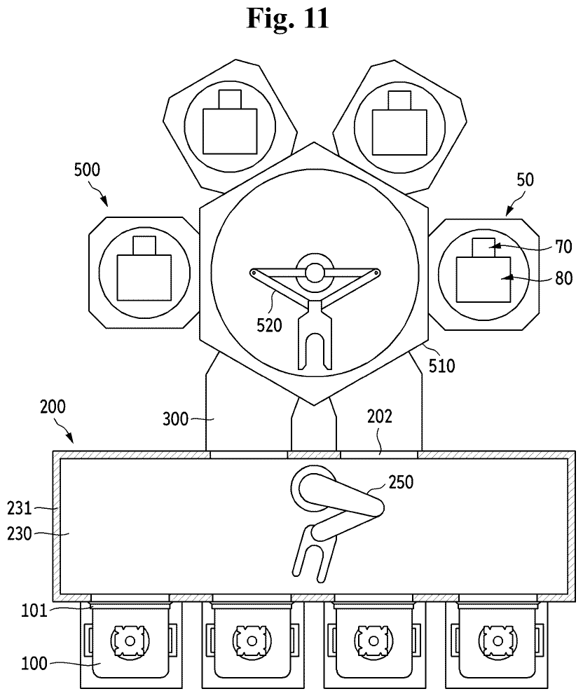

FIG. 11 is a plan view illustrating a substrate treatment apparatus according to one or more embodiments of the present disclosure.

Referring to FIG. 11, a substrate treatment cluster facility may include a substrate storage apparatus 100, a substrate transfer apparatus 200, a load lock chamber 300, and a substrate treatment apparatus 500.

The substrate storage apparatus 100 may include a plurality of slots. The substrate storage apparatus 100 may be connected to the substrate transfer apparatus 200 through a door 101. The door 101 of the substrate storage apparatus 100 may be closed when it is not necessary to transfer a substrate in order to prevent contamination of the substrate by external substances. The substrate storage apparatus 100 may be provided as a plurality of substrate storage apparatuses.

The substrate transfer apparatus 200 may include a first transfer chamber 230 and a first transfer robot 250. The substrate transfer apparatus 200 may transfer substrates taken from the substrate storage apparatus 100 to the load lock chamber 300.

A frame 231 of the first transfer chamber 230 may block the first transfer chamber 230 from the outside. Accordingly, a mini-environment may be formed inside the first transfer chamber 230.

The first transfer robot 250 may be provided inside the first transfer chamber 230. The first transfer robot 250 may transfer the substrate in both directions between the substrate storage apparatus 100 and the load lock chamber 300.

The load lock chamber 300 may connect the substrate transfer apparatus 200 to the substrate treatment apparatus 500. The substrate transfer apparatus 200 and the load lock chamber 300 may be connected to each other through a second door 202 of the substrate transfer apparatus 200. Also, the load lock chamber 300 may temporarily accommodate the transferred substrate. The second door 202 of the substrate transfer apparatus 200 may be closed when it is not necessary to transfer the substrate in order to maintain a vacuum state of the load lock chamber 300.

The substrate treatment apparatus 500 may include a second transfer chamber 510, a second transfer robot 520, and process chambers 50. The second transfer chamber 510 may be connected to the load lock chamber 300 and the plurality of process chambers 50. The second transfer robot 520 may be provided inside the second transfer chamber 510. The second transfer robot 520 may transfer the substrate between the load lock chamber 300 and the process chambers 50 or between the process chambers 50. Various semiconductor manufacturing processes may be performed in each of the process chambers 50.

In one or more embodiments, each of the plurality of process chambers 50 may include an RF meter 70 and a dummy loader 80 to measure and calibrate an RF power supplied to each of the process chambers 50. In the drawing, only the RF meter 70 and the dummy loader 80, which are attached to the upper portion of the process chambers 50, are shown, but the embodiments of the present disclosure are not limited thereto. As shown in FIG. 10, the RF meter 70 and the dummy loader 80 may be attached to sidewalls of the process chambers 50.

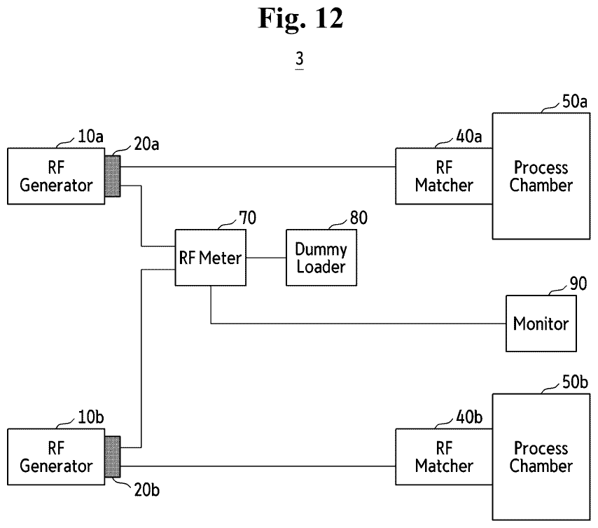

FIG. 12 is a block diagram illustrating a substrate treatment apparatus according to one or more embodiments of the present disclosure.

Referring to FIG. 12, a substrate treatment apparatus 3 may include a first RF generator 10a, a first switcher 20a, a first RF matcher 40a, a first process chamber 50a, a monitor 90, a second RF generator 10b, a second switcher 20b, a second RF matcher 40b, a second process chamber 50b, an RF meter 70, and a dummy loader 80. That is, the substrate treatment apparatus 3 may include a plurality of process chambers 50. The plurality of process chambers 50 may share a pair of the RF meter 70 and the dummy loader 80.

The first RF generator 10a and the second RF generator 10b may correspond to the RF generator 10 described with reference to FIG. 1. The first switcher 20a and the second switcher 20b may correspond to the switcher 20 described with reference to FIG. 1. The first RF matcher 40a and the second RF matcher 40b may correspond to the RF matcher 40 described with reference to FIG. 1. The first process chamber 50a and the second process chamber 50b may correspond to the process chamber 50 described with reference to FIG. 1. The first RF meter 70a and the second RF meter 70b may correspond to the RF meter 70 described with reference to FIG. 1. The first dummy loader 80a and the second dummy loader 80b may correspond to the dummy loader 80 described with reference to FIG. 1. The monitor 90 may correspond to the monitor 90 described with reference to FIG. 1. Therefore, for convenience of description, the description of each element of FIG. 12 will be omitted.

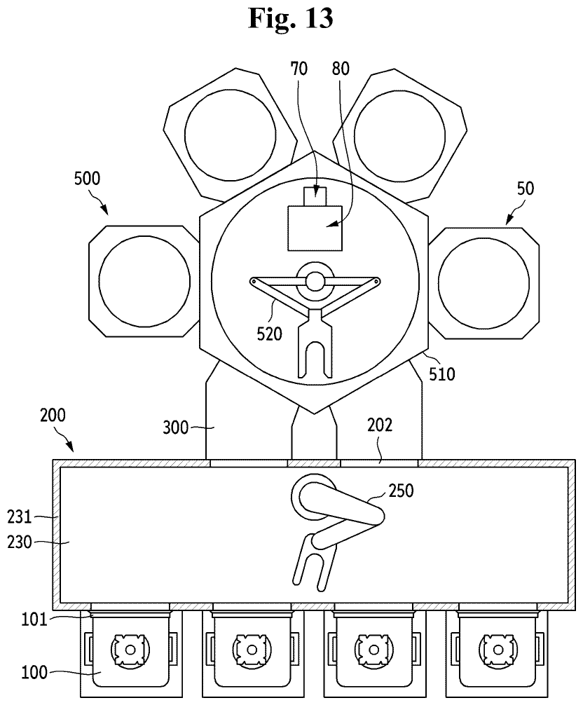

FIG. 13 is a plan view illustrating a substrate treatment apparatus according to one or more embodiments of the present disclosure. FIG. 13 corresponds to FIG. 11, and thus the description of the same elements will be omitted and the following description will be based on differences from FIG. 11.

Referring to FIG. 13, the RF meter 70 and the dummy loader 80, which are shared between the plurality of process chambers 50, may be attached to an upper portion of the second transfer chamber 510, but the embodiments of the present disclosure are not limited thereto. The RF meter 70 and the dummy loader 80 may be attached to a lower portion or a sidewall of the second transfer chamber 510.

As the plurality of process chambers 50 included in one facility share the pair of the RF meter 70 and the dummy loader 80, spatial and economic constraints may be resolved, and tool-to-tool matching between the plurality of process chambers 50 may be performed.

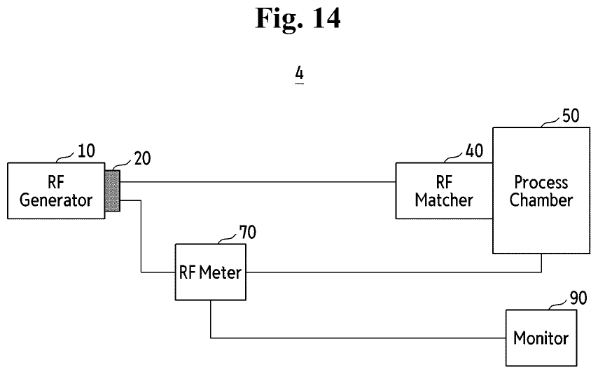

FIG. 14 is a block diagram illustrating a substrate treatment apparatus according to one or more embodiments of the present disclosure. FIG. 14 corresponds to FIG. 1, and thus the description of the same elements will be omitted and the following description will be based on differences from FIG. 1.

Referring to FIG. 14, in one or more embodiments, a substrate treatment apparatus 4 may not include a dummy loader connected to the RF meter 70. Instead, the RF meter 70 may be connected to the process chamber 50 so that the RF power provided from the RF meter 70 may be consumed in the process chamber 50.

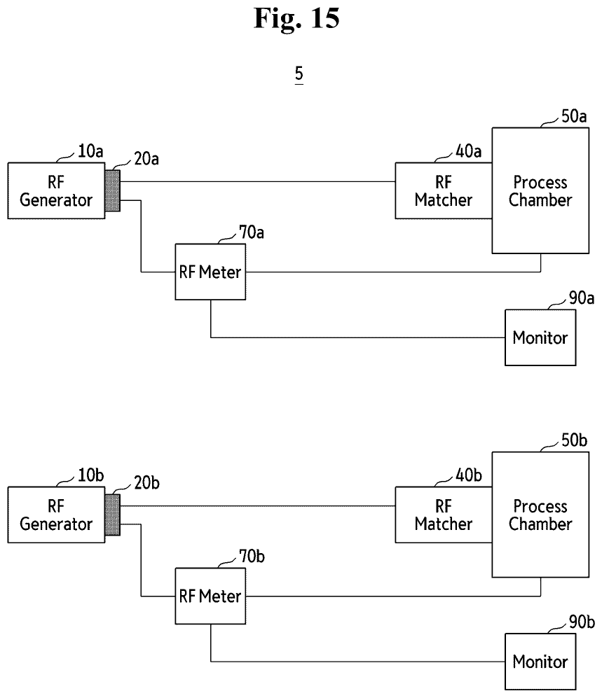

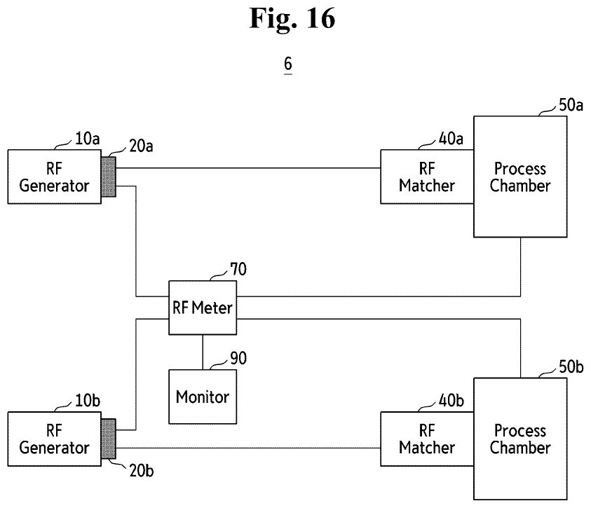

FIGS. 15 and 16 are block diagrams illustrating a substrate treatment apparatus according to one or more embodiments of the present disclosure.

Referring to FIG. 15, in one or more embodiments, a substrate treatment apparatus 5 may include a first RF generator 10a, a first switcher 20a, a first RF matcher 40a, a first process chamber 50a, a first RF meter 70a, a first monitor 90a, a second RF generator 10b, a second switcher 20b, a second RF matcher 40b, a second process chamber 50b, a second RF meter 70b, and a second monitor 90b. That is, the substrate treatment apparatus 5 may include a plurality of process chambers 50. Each process chamber 50 may operate by being independently connected to the RF generator 10, the switcher 20, the RF matcher 40, the RF meter 70, and the monitor 90.

The first RF generator 10a and the second RF generator 10b may correspond to the RF generator 10 described with reference to FIG. 1. The first switcher 20a and the second switcher 20b may correspond to the switcher 20 described with reference to FIG. 1. The first RF matcher 40a and the second RF matcher 40b may correspond to the RF matcher 40 described with reference to FIG. 1. The first process chamber 50a and the second process chamber 50b may correspond to the process chamber 50 described with reference to FIG. 1. The first RF meter 70a and the second RF meter 70b may correspond to the RF meter 70 described with reference to FIG. 1. The first monitor 90a and the second monitor 90b may correspond to the monitor 90 described with reference to FIG. 1. Therefore, for convenience of description, the description of each element of FIG. 15 will be omitted.

Referring to FIG. 16, in one or more embodiments, a substrate treatment apparatus 6 may include a first RF generator 10a, a first switcher 20a, a first RF matcher 40a, a first process chamber 50a, a monitor 90, a second RF generator 10b, a second switcher 20b, a second RF matcher 40b, a second process chamber 50b, and an RF meter 70. That is, the substrate treatment apparatus 6 may include a plurality of process chambers 50. The plurality of process chambers 50 may share one RF meter 70.

The first RF generator 10a and the second RF generator 10b may correspond to the RF generator 10 described with reference to FIG. 1. The first switcher 20a and the second switcher 20b may correspond to the switcher 20 described with reference to FIG. 1. The first RF matcher 40a and the second RF matcher 40b may correspond to the RF matcher 40 described with reference to FIG. 1. The first process chamber 50a and the second process chamber 50b may correspond to the process chamber 50 described with reference to FIG. 1. The first RF meter 70a and the second RF meter 70b may correspond to the RF meter 70 described with reference to FIG. 1. The monitor 90 may correspond to the monitor 90 described with reference to FIG. 1. Therefore, for convenience of description, the description of each element of FIG. 16 will be omitted.

According to the substrate treatment apparatuses 1 to 6 described with reference to FIGS. 1 to 16, when a user performs verification and calibration for the RF generator 10 that supplies power to the process chamber 50, the RF meter 70 embedded in the substrate treatment apparatus may be used without a separate external device. Accordingly, the power may be constantly monitored in the idle state of the process chamber 50, whereby the change in power over time may be minimized. As a result, the substrate treatment apparatuses 1 to 6, which make sure of uniformity and stability of the process, may be provided.

At least one of the components, elements, modules, units, or the like (collectively “components” in this paragraph) represented by a block or an equivalent indication (collectively “block”) in the above embodiments including the drawings such as FIGS. 1, 2, 4-10, and 13-16, for example, RF generators, switchers, RF meters, monitors, dummy loaders, and RF matchers, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

Although the embodiments of the present disclosure have been described with reference to the accompanying drawings, it will be apparent to those skilled in the art that the present disclosure may be manufactured in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. A substrate treatment apparatus comprising:
a first process chamber configured to provide a treatment to a substrate;
a first radio frequency (RF) generator configured to generate a first RF signal;
a first RF matcher configured to match an impedance between the first RF generator and the first process chamber and to provide the first RF signal to the first process chamber;
a first RF meter configured to measure a power of the first RF signal; and
a first switcher configured to connect the first RF generator to either the first RF matcher or the first RF meter.

2. The substrate treatment apparatus of claim 1, further comprising:
a second process chamber different from the first process chamber;
a second RF generator configured to generate a second RF signal; and
a second RF matcher configured to match an impedance between the second RF generator and the second process chamber and to provide the second RF signal to the second process chamber.

3. The substrate treatment apparatus of claim 2, further comprising:
a second RF meter configured to measure a power of the second RF signal; and
a second switcher configured to connect the second RF generator to either the second RF matcher or the second RF meter.

4. The substrate treatment apparatus of claim 2, further comprising a second switcher configured to connect the second RF generator to either the second RF matcher or the first RF meter.

5. The substrate treatment apparatus of claim 4, wherein, based on the first process chamber being in an idle state, the first switcher is further configured to connect the first RF generator to the first RF meter, and the first RF meter is configured to measure the power of the first RF signal received from the first RF generator, and
wherein, based on the second process chamber being in an idle state, the second switcher is further configured to connect the second RF generator to the first RF meter, and the first RF meter is configured to measure the power of the second RF signal.

6. The substrate treatment apparatus of claim 1, wherein, based on the first process chamber being in an idle state and the first switcher connecting the first RF generator to the first RF meter, the first RF meter is configured to measure the power of the first RF signal and to provide the first RF generator with calibration data generated based on a first measured power measured by the first RF meter and a first set power set to be output by the first RF generator.

7. The substrate treatment apparatus of claim 6, wherein the first RF generator is configured to provide, to the first RF meter, a third RF signal calibrated based on the calibration data,
wherein the first RF meter is further configured to measure a power of the third RF signal, and
wherein the first switcher is further configured to disconnect the first RF generator from the first RF meter based on a second measured power measured by the first RF meter being the same as the first set power.

8. The substrate treatment apparatus of claim 7, wherein, based on the first switcher connecting the first RF generator to the first RF matcher, the first RF generator is configured to provide the third RF signal to the first RF matcher.

9. The substrate treatment apparatus of claim 6, further comprising a monitor connected to the first RF meter,
wherein the monitor is configured to display a magnitude of the first measured power, to receive the calibration data, and to provide the received calibration data to the first RF meter.

10. The substrate treatment apparatus of claim 1, further comprising a dummy loader connected to the first RF meter,
wherein the dummy loader is configured to consume power received by the dummy loader from the first RF meter.

11. A method for operating a substrate treatment apparatus, the method comprising:
connecting a first radio frequency (RF) generator of the substrate treatment apparatus to an RF meter by a first switcher of the substrate treatment apparatus;
measuring, by the RF meter, a power of a first RF signal generated by the first RF generator;
providing, to the first RF generator, calibration data generated based on a first measured power measured by the RF meter and a first set power set to be output by the first RF generator;
providing, to the RF meter by the first RF generator, a second RF signal calibrated based on the calibration data;
measuring, by the RF meter, a power of the second RF signal; and
based on a second measured power measured by the RF meter being the same as the first set power, disconnecting the first RF generator from the RF meter by the first switcher.

12. The method of claim 11, further comprising:
connecting the first RF generator to a first processing chamber of the substrate treatment apparatus by the first switcher; and
providing, by the first RF generator, the second RF signal to the chamber.

13. The method of claim 12, further comprising matching, by a first RF matcher of the substrate treatment apparatus, an impedance between the first RF generator and the first process chamber.

14. The method of claim 12, further comprising:
connecting, by a second switcher of the substrate treatment apparatus, a second RF generator of the substrate treatment apparatus to the RF meter;
measuring, by the RF meter, a power of a third RF signal generated by the second RF generator;
providing, to the second RF generator, second calibration data generated based on a third measured power measured by the RF meter and a second set power set to be output by the second RF generator;
providing, to the RF meter by the second RF generator, a fourth RF signal calibrated based on the second calibration data;
measuring, by the RF meter, a power of the fourth RF signal; and
based on a fourth measured power measured by the RF meter being the same as the second set power, disconnecting the second RF generator from the RF meter by the second switcher.

15. The method of claim 14, further comprising:
connecting the second RF generator to a second process chamber of the substrate treatment apparatus by the second switcher; and
providing, by the second RF generator, the fourth RF signal to the second process chamber.

16. The method of claim 11, further comprising:
displaying a magnitude of the first measured power by a monitor of the substrate treatment apparatus;
receiving the calibration data by the monitor; and
providing, by the monitor, the calibration data to the RF meter.

17. The method of claim 11, further comprising consuming, by a dummy loader of the substrate treatment apparatus, power received by the dummy loader from the RF meter.

18. The method of claim 12, wherein the first process chamber is in an idle state.

19. A substrate treatment apparatus comprising:
a first process chamber configured to provide a treatment to a substrate;
a second process chamber different from the first process chamber;
a first radio frequency (RF) generator configured to generate a first RF signal;
a second RF generator configured to generate a second RF signal;
a first RF matcher configured to match an impedance between the first RF generator and the first process chamber and to provide the first RF signal to the first process chamber;
a second RF matcher configured to match an impedance between the second RF generator and the second process chamber and to provide the second RF signal to the second process chamber;
an RF meter configured to measure a power of the first RF signal or a power of the second RF signal;
a dummy loader configured to consume power received by the dummy loader from the RF meter;
a first switcher configured to connect the first RF generator to either the first RF matcher or the RF meter; and
a second switcher configured to connect the second RF generator to either the second RF matcher or the RF meter.

20. The substrate treatment apparatus of claim 19, wherein the first process chamber and the second process chamber are in an idle state,
wherein, based on the first process chamber being connected to the RF meter by the first switcher:
the RF meter is configured to measure a power of the first RF signal and to provide, to the first RF generator, calibration data generated based on a first measured power measured by the RF meter and a first set power set to be output by the first RF generator,
the first RF generator is configured to provide, to the RF meter, a third RF signal calibrated based on the calibration data,
the RF meter is configured to measure a power of the third RF signal, and
the first switcher is configured to disconnect the first RF generator from the RF meter based on a second measured power measured by the RF meter being the same as the first set power, and
wherein, based on the second process chamber being connected to the RF meter by the second switcher:
the RF meter is configured to measure a power of a fourth RF signal generated by the second RF generator and to provide, to the second RF generator, second calibration data generated based on a third measured power measured by the RF meter and a second set power set to be output by the second RF generator,
the second RF generator is configured to provide, to the RF meter, a fifth RF signal calibrated based on the second calibration data,
the RF meter is configured to measure a power of the fifth RF signal, and
the second switcher is configured to disconnect the second RF generator from the RF meter based on a fourth measured power measured by the RF meter being the same as the second set power.
